(19) United States
(12) Patent Application Publication
(10) Pub. No.: US 2003/0089613 A1
(43) Pub. Date: May 15, 2003

(54) Method of selectively electroplating by screen-plating technology

(76) Inventor: Chang Yu Ching, Taoyuan (TW)

Correspondence Address: Chun M. Ng, Perkins Colie LLp, 1201 Third Avenue, Suite 4800, Seattle, WA, 98101, US

(21) Appl. No.: 10/003,135

(22) Filed: Nov. 15, 2001

(51) Int. Cl. C25D 5/02; H05K 3/00; C23C 28/00; C25D 5/48

(52) U.S. Cl. 205/125; 205/183; 205/221; 205/118

(57) ABSTRACT

The present invention is to provide a method of selective electroplating comprises a substrate. The substrate may include printed circuir board or other plating metal article on printed circuit board surface specified region. Then, a wet film formed on the substrate by screen-printing, wherein the wet film is photo-sensitivty. Next, it is hardening the wet film, and then exposing the wet film. Next, it is developing the wet film to expose some region for forming metal on the substrate. A metal layer formed on the substrate. Finally, it is stripping the wet film.

### FIELD OF THE INVENTION

The present invention relates to an electroplating process, and more specifically, to a method of forming wet film by applying screen-plating technology.

### BACKGROUND OF THE INVENTION

Integrated circuits industry and fabrication involve the formation of semiconductor wafers, integrated circuits and chip package. With the advent of Ultra Large Scale Integrated (ULSI) circuits technologies, it has been a trend to scale down the geometry dimension of semiconductor devices and increase the density of semiconductor devices per unit area of silicon wafer. Thus, the sizes of devices, such as memory cells, have gotten smaller and smaller such that the area available for a single device has become very small. Further, the manufacturers of the devices are striving to reduce the sizes while simultaneously increasing their speed. Chip scaled package is the method to thrink the size of the package. Further, various types of package have been developed. No matter what type of the package is, most of the packages are divided into individual chips before they are packaged. However, the wafer level packaging is a trend for the semiconductor package. The dice are packaged before they are divided into individual units.

The increasing clock rate of digital systems and the desire will pack greater functionality into smaller spaces. Therefore, the number of a package's leads becomes more and more. An important consideration in making small, high speed and high-density devices is providing packages capable of the spreading heat generated by the devices. A further problem confronting the technology is the relentless need for more I/O per chip.

One response to the requirement of providing packages for high speed and density devices has been developed. One such package type is ball grid array (BGA) that uses a bismaleimidetraizine (BT) as a substrate. For high I/O count IC chips, Ball grid array (BGA) packages have been used that can have more I/Os than QFPs. BGAs connect to PCBs using balls instead of pins or leads. The circuir board for communication and loading chips need to develop manufacturing method as the above mentioned technique development. For example, more function and more operation abilities chips need more contacts and more circuit board complicated circuit layout.

As the above mentioned, the requirement of circuit board are high density and small line width, and it is a challenge of circuit board manufacturing technic. It needs to face and resolve the problem of plating permeation of prior art. FIG. 1 shows a cross sectional substrate illustrating an electroplating metal formed on a circuit board according to the prior art. Firstly, dry film 1 is formed on circuit board 200 by using coating. The dry film 1 is to be exposed and developed to form the specified pattern for electroplating metal region, then the electroplated metal 8 is formed on the circuit board 200. Finally, the dry film 1 will be removed. The virtual line inclosure region, showed in FIG. 1, is the plating permeation. The reason of the plating permeation are included: viscosity of the dry film on the circuit board, the characteristic of the plating metal material. etc. The common solution of the plating permeation issue is using thinker dry film. However, it will increase the manufacture cost.

Moreover, another solution of the plating permeation provide ink as material and use the method of coating ink to form wet film on circuit board. The method of coating ink by using curtain coater can solve the plating permeation issue. The method are minute and complicated in process, the cost is higher than the method which involves the usage of dry film with thicker thinkness. The prior art method induces higher cost in related equipments and machines. It has solved the plating permeation issue, but it was not competitiveness in market.

### SUMMARY OF THE INVENTION

The object of the present invention is to provide a method of selective electroplating to solve the problem of plating permeation of prior art.

The method of the present invention is to provide an novel screen-printing technology, wherein screen-printing type ink forms wet film on an article surface through scraper and mesh.

The present invention process is less difficulty in technic, and much less cost in equipments.

The method for selective electroplating is described as the following:

Firstly, a substrate is provided. The substrate may include printed circuir board or other plating metal article on printed circuit board surface specified region. Then, a wet film is formed on the substrate by screen-printing, wherein the wet film is photo-sensitivty. Next step is to harden the wet film 6, and then exposing the wet film. Next, the wet film is developed to expose some region for forming metal on the substrate. A metal layer is formed on the substrate. Finally, the wet film is stripped.

### BRIEF DESCRIPTION OF THE DRAWINGS

FIG. 1 is a cross section view of electroplating metal on circuit board according to the prior art.

FIG. 2 is a schematic diagram view of forming wet film on article according to the present invention.

FIG. 3 is a cross section view of forming pattern on wet film according to the present invention.

FIG. 4 is a cross section view of forming metal on an article according to the present invention.

FIG. 5 is a flow chart according to the embodiment of the present invention.

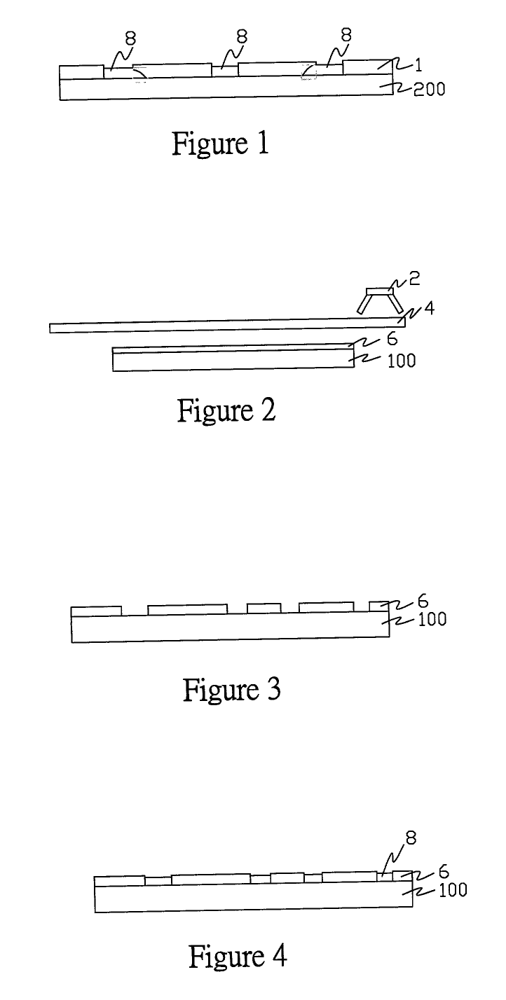

### DETAILED DESCRIPTION OF THE PREFERRED EMBODIMENT

The present invention discloses a method of selectivly electroplating to resolve the problem of plating permeation of prior art. The method of forming dry film on article surface is the prior art provided. The method of the present invention introduces the screen-printing technology applied for other process, wherein the wet film is formed on article surface by using screen-printing type ink through a mesh. The formed wet film has extremely good characteristic to avoid the plating permeation issue of prior art by adjusting ink combination.

Transferring screen-printing technology to the present invention process may reduce the manufacture cost. A method in accordance with the invention will be described in conjunction with and illustrative embodiment of the invention.

Please referring to FIG. 2, a substrate 100 is provided, the substrate 100 may include printed circuit board coated by prevention solder liquid, other plating metal article on printed circuit board surface specified region. Next, a wet film 6 may be formed on substrate 100. For example, screen-printing can be used to form the wet film 6. The wet film 6 is photo-sensitive, it is similar to the photoresist used in Ics.

The step for forming the wet film 6 includes firstly stirring the ink before the ink is applied, and then paddling the ink for a predetermined time. The ink comprises 2˜3 weight percentage de-floating agent to avoid ink creating bobble in ink barrel stirring and scraping. The stirring ink time is about 5˜10 minutes, and the paddling ink time is about 20˜30 minutes.

Next, using the scraper 2 scraped the ink over the mesh 4, therefore the ink covered uniformly on the substrate 100 by means of mesh 4. The wet film 6 formed by the ink is subsequently drying. The temperature of drying ink is in room temperature or below 40° C. temperature about 10˜15 minutes. The formed wet film 6 is photo-senstivity.

An embodiment of aforementioned example includes the usage of the ink of Nippon company's OPTO-ER N-400G(H) type. In order to enhance the viscousness of the wet film 6, the ink solidification combination must be increased. Next, hardening the wet film 6, it can be done by curing of heater. The step removed humidity by thermal energy, thus the wet film 6's structure will be more densified.

Turning to FIG. 3, further steps are similar to the semiconductor integrated circuit photolithography process, and the wet film 6 acts as the photoresist. Then, we can use the exposure process to expose the wet film 6. It may be using mask or film exposure method to transfer the specified pattern to the wet film 6.

The wet film 6 chemistry structure will be changed by means of different exposure energy. After developing, the specified pattern wet film 6 is formed on substrate 100. The removal wet film 6 region is thereinafter electroplating region.

Please referring to FIG. 4, metal 8 is formed on substrate 100. Finally, remove the wet film 6. The method of metal 8 forming on substrate 100 can be executed by using electroplating or non-electric electroplating, depending on the electroplating metal variety. For example, solder contact can be made by using the method of screen-printing covering tin grease. The method of removal wet film 6 depend on wet film 6's composition. However, in the present invention, we can remove the wet film 6 by using Na(OH) solution.

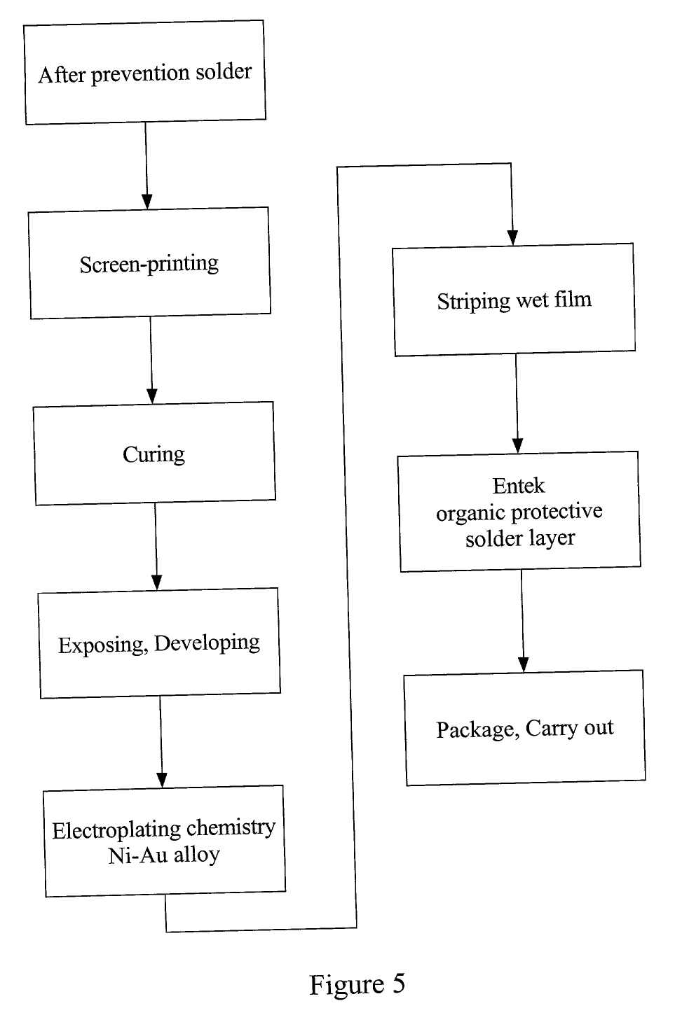

Turning to FIG. 5, a flow chart of an embodiment of electroplating Ni—Au metal circuit board for cellular phone. The first step is to coat the prevention solder paint on cellular phone circuit board, then the wet film is formed on cellular phone circuit board by using the screen-printing technology. It can use the ink of Nippon company's OPTO-ER N-400G(H) type. The requirement viscosity of wet film is about 80˜90 poise, and the T-number of mesh are changeable. Next, the wet film is hardened by curing 10 minutes, and its temperature is about 100° C. We can expose the wet film by using film exposure method, the specified wet film pattern formed after developing. Then, it prceeded electroplating chemical Ni—Au alloy, its comprising Ni composition with thickness about 100˜200μ, Au composition with thickness about 2˜5μ.

In order to enhance the hard-wearing and hard-scraping properties, the touch of board surface of cellular phone circuit board will be selected electroplating chemical Ni—Au alloy to improve the plating permeation as using dry film in the prior art.

The wet film was stripped by Na(OH) solution. Finally, an Entek organic protective solder layer is formed on chemical Ni—Au alloy metal layer surface after stripping the wet film to avoid such metal layer oxidation as contact with air. The Entek means an organic thin film, and its main composition is BTA. The feature of the BTA is that the film will not deposite on a metal layer.

A further embodiment, electroplating soft Au on printed circuit board (PCB) is the key process for chip scale package of high level products. In electroplating soft Au process of the present invention, the thickness of the Ni compostion is above 200μ, and the thickness of the Au composition thickness is about 20˜40μ. It is thicker than electroplating chemical Ni—Au alloy, and better than electroplating chemical Ni—Au alloy in avoiding plating permeation.

A screen-printing technology in accordance with the present invention can greatly reduce cost, and enhance market competitiveness. Moreover, the present invention also resolves the problem of plating permeation of prior art, and screen-printing technology process is easy to control.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A method of selective electroplating comprising:
providing a substrate;
forming a wet film on said substrate by screen-printing, wherein said wet film is photo-sensitivty;
hardening said wet film;
exposing said wet film;
developing said wet film to expose predertermined region for forming metal on said expose predertermined region of said substrate;
forming a metal layer on said substrate; and
stripping said wet film.

2. The method of claim 1, further comprising following steps to form said wet film on said substrate by said screen-printing:
providing an ink which is the material for forming said wet film;
stirring said ink;
paddling said ink;
coating said ink on said substrate by using scraper and mesh; and
drying said ink to form said wet film.

3. The method of claim 2, wherein said ink comprises 2˜3 weight percentage de-floating agent.

4. The method of claim 2, wherein the time for stirring said ink is about 5˜10 minutes.

5. The method of claim 2, wherein the time for paddling said ink is about 20˜30 minutes.

6. The method of claim 2, wherein the temperature for drying said ink is in room temperature for about 10˜15 minutes.

7. The method of claim 2, wherein the temperature for drying said ink is in below 40° C. for about 10˜15 minutes.

8. The method of claim 1, further comprising forming an organic protective solder layer on said metal layer surface after stripping said wet film to avoid said metal layer oxidation as contact with air.

9. The method of claim 1, wherein said substrate comprising printed circuit board (PCB).

10. The method of claim 1, wherein said substrate comprises circuit board for cellular phone.

11. The method of claim 1, wherein said metal layer formed on said substrate comprises electroplating chemical Ni—Au alloy on said substrate or electroplating soft Au alloy on said substrate.

12. The method of claim 11, wherein said chemical Ni—Au alloy comprises Ni composition with thickness about 100˜200μ, Au composition with thickness about 2˜5μ.

13. The method of claim 1, wherein said metal layer formed on said substrate comprises electroplating soft Au alloy on said substrate.

14. The method of claim 13, wherein said electroplating soft Au alloy comprises Ni composition with thickness above 200μ, Au composition with thickness about 20˜40μ.

15. The method of claim 1, wherein said wet film can be stripped by Na(OH) solution.

16. The method of claim 1, wherein said wet film is hardened by curing of heater.
